(19) United States
(12) Patent Application Publication
(10) Pub. No.: US 2020/0175244 A1
(43) Pub. Date: Jun. 4, 2020

(54) PANEL STRUCTURE

(71) Applicant: ASTI GLOBAL INC., TAIWAN, Changhua County (TW)

(72) Inventor: CHIEN-SHOU LIAO, New Taipei City (TW)

(21) Appl. No.: 16/420,437

(22) Filed: May 23, 2019

(30) Foreign Application Priority Data
Nov. 30, 2018 (TW) 107143019

(51) Int. Cl. G06K 9/00; H01L 27/15; H01L 27/146

(52) U.S. Cl. CPC G06K 9/0004; H01L 27/14678; H01L 27/156

(57) ABSTRACT

A panel structure includes a circuit substrate, a light-emitting component and a sensing component. The circuit substrate includes a plurality of control circuits. The light-emitting component includes a plurality of light-emitting elements electrically connected to the circuit substrate. The sensing component includes a plurality of sensing elements electrically connected to the circuit substrate. The light-emitting elements are electrically connected to the control circuits, and some or all of the light-emitting elements are staggeringly disposed with the sensing elements on the circuit substrate.

This application claims the benefit of priority to Taiwan Patent Application No. 107143019, filed on Nov. 30, 2018. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a panel structure, and more particularly to a panel structure including a plurality of light-emitting diodes.

### BACKGROUND OF THE DISCLOSURE

Light-emitting diodes (LEDs) are widely used nowadays due to their excellent light quality and high luminous efficiency. Generally, in order for a display device using a light-emitting diode as a light-emitting element to have better color performance, a conventional display device adopts a combination of red, green, and blue light-emitting diode chips to form a full color light-emitting diode display device. The full-color light-emitting diode display device can respectively emit three colors of red, green and blue light through three kinds of red, green and blue light-emitting diode chips, so that a full-color light is formed to display relevant information after the mixing of light. However, the LED display device of the related art still has room for improvement.

### SUMMARY OF THE DISCLOSURE

In response to the above-referenced technical inadequacies, the present disclosure provides a panel structure.

In one aspect, the present disclosure provides a panel structure including a circuit substrate, a light-emitting component, and a sensing component. The circuit substrate includes a plurality of control circuits. The light-emitting component includes a plurality of light-emitting elements electrically connected to the circuit substrate. The sensing component includes a plurality of sensing elements electrically connected to the circuit substrate. The light-emitting elements are electrically connected to the plurality of control circuits, and some or all of the light-emitting elements are staggeringly disposed with the sensing elements on the circuit substrate.

In one aspect, the present disclosure provides a panel structure including a circuit substrate, a light-emitting component, and a sensing component. The light-emitting component includes a plurality of light-emitting elements electrically connected to the circuit substrate as an image display. The sensing component includes one or more sensing elements electrically connected to the circuit substrate as an image sensor. Some or all of the light-emitting elements are staggeringly disposed with the sensing elements on the circuit substrate. Therefore, one of the beneficial effects of the present disclosure is that the panel structure provided by the present disclosure has the technical feature of “some or all of the light-emitting elements being staggeringly disposed with the sensing elements on the circuit substrate,” so that a multi-purpose panel structure can be provided. By using a combination of the light-emitting elements and the sensing elements, the panel structure can be applied to instruments such as fingerprint readers or endoscopes.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a top view of a panel structure according to a first embodiment of the present disclosure.

FIG. 2 is an enlarged schematic view of a portion II of FIG. 1.

FIG. 3 is a cross-sectional view of a sub-millimeter LED.

FIG. 4 is a side cross-sectional view of a micro LED.

FIG. 5 is a schematic diagram showing a fingerprint reader according to the present disclosure, including a light-emitting element and a sensing element, in operation.

FIG. 6 is a top view of the panel structure according to a second embodiment of the present disclosure.

FIG. 7 is an enlarged schematic view of a portion VII of FIG. 6.

FIG. 8 is a schematic diagram showing an endoscope assembly according to the present disclosure, including a light-emitting element and a sensing element, in operation.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

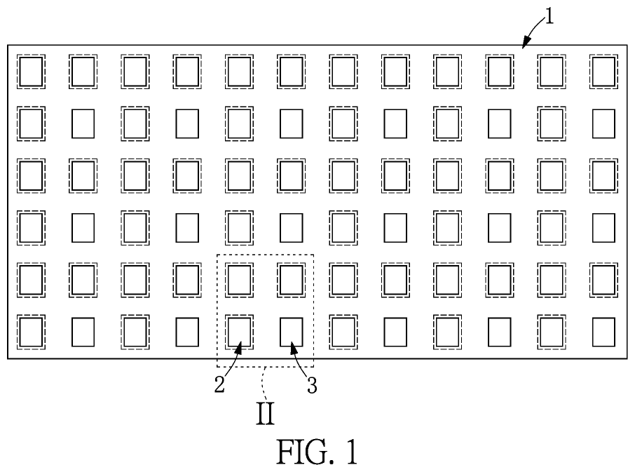

Referring to FIG. 1 to FIG. 4, a first embodiment of the present disclosure provides a panel structure including: a circuit substrate 1, a light-emitting component 2, and a sensing component 3.

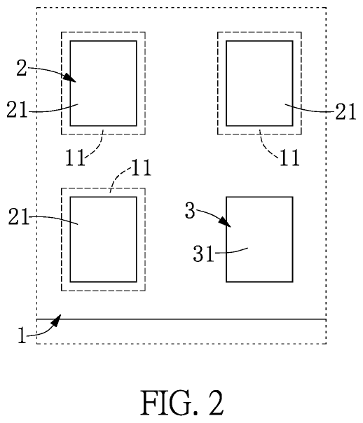

Firstly, as shown in FIG. 1 and FIG. 2, the circuit substrate 1 includes a plurality of control circuits 11 embedded in the circuit substrate 1. The control circuit 11 may be a CMOS (Complementary Metal-Oxide-Semiconductor) control circuit having a source, a drain, and a gate. However, the present disclosure is not limited thereto. The light-emitting component 2 is electrically connected to the circuit substrate 1. The light-emitting component 2 includes a plurality of light-emitting elements 21 electrically connected to the circuit substrate 1. Specifically, each light-emitting element 21 is disposed above the corresponding one of the electrically connected the control circuit 11. The sensing component 3 is electrically connected to the circuit substrate 1. The sensing component 3 includes a plurality of sensing elements 31 electrically connected to the circuit substrate 1. The sensing element 31 and some or all of the light-emitting elements 21 are staggeringly disposed with the sensing elements on the circuit substrate 1. Specifically, each sensing element 31 is respectively disposed above the control circuit 11 corresponding to the electrical connection.

In the first embodiment, the light-emitting elements 21 are arranged in an array layout on the circuit substrate 1. The light sources generated by the light-emitting elements 21 cooperate with each other to form a display image, that is, the light-emitting component 2 can be used as an image display. A plurality of sensing elements 31 are arranged in an array layout on the circuit substrate 1. The plurality of sensing elements 31 cooperate with each other to capture an image information, that is, the sensing component 3 can be used as an image sensor. A plurality of light-emitting elements 21 and a plurality of sensing elements 31 are regularly staggered on the substrate 1.

Specifically, the light-emitting elements 21 may be a red light-emitting element, a green light-emitting element, or a blue light-emitting element. The red light-emitting element, the green light-emitting element and the blue light-emitting element disposed adjacent to each other, under the control of the control circuit 11, can generate three colors of light (red, green and blue) or overlap to form full-color light, and can constitute one of the pixels of the displayed image.

In this embodiment, the light-emitting elements 21 may be LED (Light-Emitting Diodes), and may be classified into sub-millimeter LED (Mini LED) and micro LED (Micro LED) according to sizes of the light-emitting elements and whether the light-emitting elements have substrates, but the present disclosure is not limited thereto.

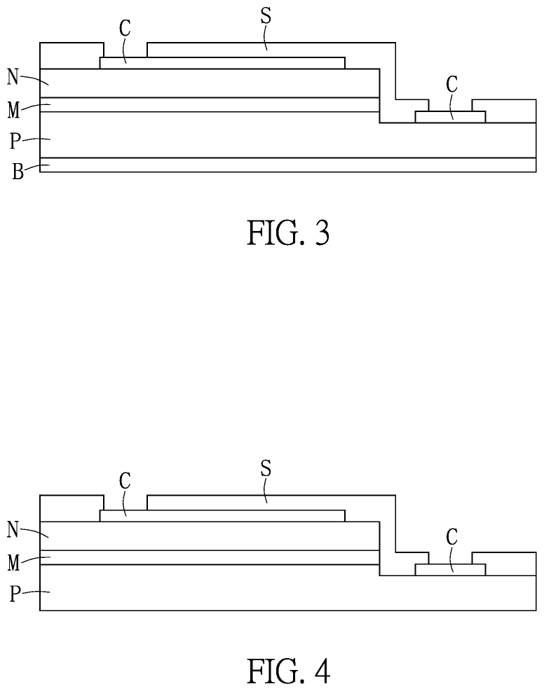

Referring to FIG. 3, the sub-millimeter LED includes a substrate B, an n-type semiconductor N, a light-emitting layer M, a p-type semiconductor P, two solder pads C, and an insulation layer S that are in a stacked arrangement. The n-type semiconductor N, the light-emitting layer M, and the p-type semiconductor P are disposed on the substrate B. The light-emitting layer M is disposed between the n-type semiconductor N and the p-type semiconductor P. The two solder pads C are respectively disposed on the n-type semiconductor N and the p-type semiconductor P. The insulation layer S is disposed on the n-type semiconductor N, the light-emitting layer M, the p-type semiconductor P, and the two solder pads C, and a portion of each of the two solder pads C are both exposed from the insulation layer S. The substrate B is a sapphire material layer, the n-type semiconductor N may be an n-type gallium nitride material layer or an n-type gallium arsenide material layer, the light-emitting layer M is a multiple quantum well structure layer (Multiple Quantum Well, MQW), and the p-type semiconductor P can be a p-type gallium nitride material layer or a p-type gallium arsenide material layer, but the present disclosure is not limited thereto. The substrate B can also be a base layer of quartz, glass, tantalum or any material. The materials of n-type semiconductor N and the p-type semiconductor P can be selected according to the color of the generated light source. However, the above-mentioned examples are only one of the possible embodiments and the present disclosure is not limited thereto.

Referring to FIG. 4, the micro LED includes an n-type semiconductor N, a light-emitting layer M, a p-type semiconductor P, two solder pads C, and an insulation layer S that are in a stacked arrangement. The n-type semiconductor N, the light-emitting layer M, and the p-type semiconductor P are disposed on the substrate B. The light-emitting layer M is disposed between the n-type semiconductor N and the p-type semiconductor P. The two solder pads C are respectively disposed on the n-type semiconductor N and the p-type semiconductor P. The insulation layer S is disposed on the n-type semiconductor N, the light-emitting layer M, the p-type semiconductor P, and the two solder pads C, and a portion of each of the two solder pads C are both exposed from the insulation layer S. The n-type semiconductor N may be an n-type gallium nitride material layer or an n-type gallium arsenide material layer, the light-emitting layer M is a multi-quantum well structure layer, and the p-type semiconductor P may be a p-type gallium nitride material layer or a p-type gallium arsenide material layer, but the present disclosure is not limited thereto. The materials of n-type semiconductor N and p-type semiconductor P can be selected according to the color of the generated light source. However, the above-mentioned examples are only one of the possible embodiments and the present disclosure is not limited thereto.

Further, when at least one of the light-emitting elements 21 and at least one of the sensing elements 31 interact with each other, a surface sensor for an object can be constructed. The light-emitting element 21 can generate a projection light source and project the light source to an object. After the projection light source is reflected by the object, a reflection light source is formed, and the reflection light source is projected to the sensing element 31 so that the sensing element 31 captures the image information of the object. For example, the surface sensor for an object can be a fingerprint reader.

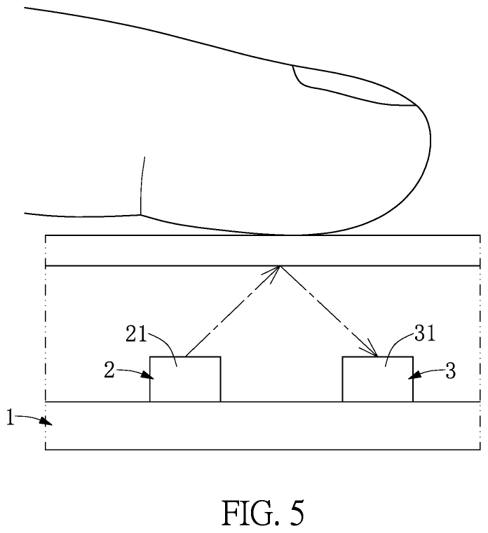

Referring to FIG. 5, a projection light source generated by the light-emitting element 21 is projected to the fingerprint of the finger. After the projection light source is reflected by the finger, a reflection light source is generated, and the reflected light source is projected to the sensing element 31. At this time, the sensing element 31 can obtain the fingerprint image information of the finger to recognize the fingerprint. The panel structure of the first embodiment is evenly distributed with the sensing elements 31, so that fingerprint recognition can be performed across the entire panel structure. However, the above-mentioned examples are only one of the possible embodiments and the present disclosure is not limited thereto.

### Second Embodiment

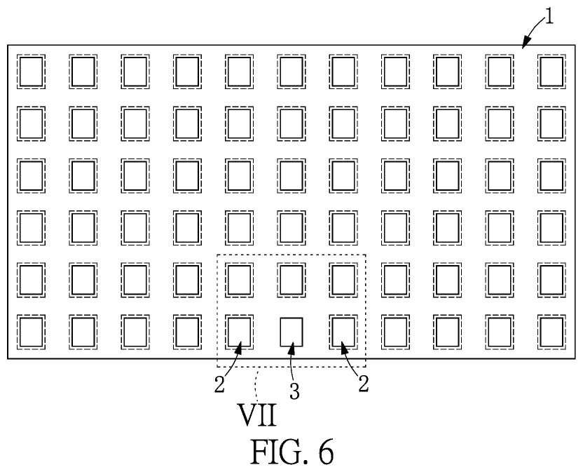

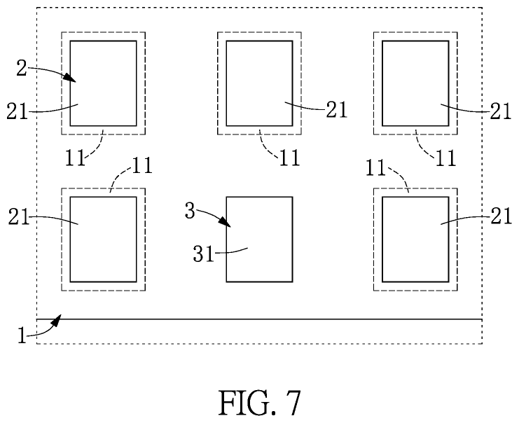

Referring to FIG. 6 to FIG. 7, a second embodiment of the present disclosure provides a panel structure including: a circuit substrate 1, a light-emitting component 2, and a sensing component 3.

The circuit substrate 1 includes a plurality of control circuits 11 embedded in the circuit substrate 1. The light-emitting component 2 includes a plurality of light-emitting elements 21 electrically connected to the circuit substrate 1. The sensing component 3 includes a sensing element 31 (or a plurality of sensing elements 31) that is electrically connected to the circuit substrate 1. The structure of the circuit substrate 1, the light-emitting component 2, and the sensing component 3 in the panel structure of the second embodiment is similar to that of the first embodiment, except that the sensing component 3 in the second embodiment has only one sensing element 31.

In the second embodiment, the light-emitting elements 21 are arranged in an array layout on the circuit substrate 1. The light sources generated by the light-emitting elements 21 cooperate with each other to form a display image, that is, the light-emitting component 2 can be used as an image display. The sensing element 31 is centrally disposed on the edge of the circuit substrate 1 and surrounded by the light-emitting elements 21, and the sensing element 31 has a function of capturing an image information, that is, the sensing component 3 can be used as an image sensor.

When a plurality of light-emitting elements 21 and the sensing element 31 interact with each other, a surface sensor for an object such as a fingerprint reader can be constructed. That is to say, the circuit substrate 1 of the second embodiment is provided with part of the sensing element 31, and may also have a function of fingerprint recognition.

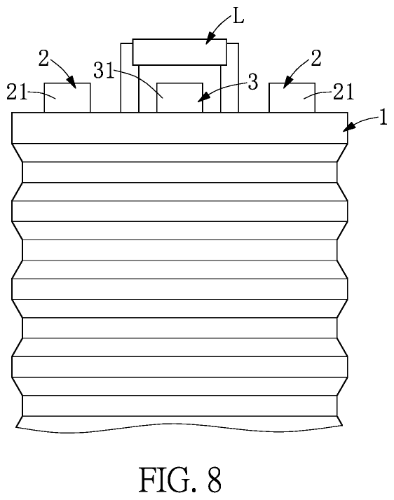

In addition, the panel structure of the first embodiment or the second embodiment can be applied to the endoscope assembly through the cooperation of at least one light-emitting element 21 and at least one sensing element 31. Referring to FIG. 8, the light-emitting element 21 can generate a projection light source and project it to an object (e.g., the organ to be observed). After the projection light source is reflected by the object, a reflection light source is formed, and the reflection light source is received by a sensing module 31 through a camera module L, thereby capturing image information. However, the above-mentioned examples are only one of the possible embodiments and the present disclosure is not limited thereto.

In conclusion, one of the beneficial effects of the present disclosure is that the panel structure provided by the present disclosure has the technical feature of “some or all of the light-emitting elements are staggeringly disposed with the sensing elements on the circuit substrate,” so that a multi-purpose panel structure can be provided. By using a combination of the light-emitting elements and the sensing elements, the panel structure can be applied to instruments such as fingerprint readers or endoscopes.

Furthermore, by arranging the light-emitting elements in an array layout, the light sources generated by the light-emitting elements can cooperate with each other to form a display image. By arranging the sensing elements in an array, the sensing elements can cooperate with each other to capture an image information.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A panel structure, comprising:
a circuit substrate including a plurality of control circuits;
a light-emitting component including a plurality of light-emitting elements electrically connected to the circuit substrate; and
a sensing component including a plurality of sensing elements electrically connected to the circuit substrate;
wherein the light-emitting elements are electrically connected to the control circuits, and some or all of the light-emitting elements are staggeringly disposed with the sensing elements on the circuit substrate.

2. The panel structure according to claim 1, wherein the light-emitting elements are arranged in an array layout on the circuit substrate, and the light sources generated by the light-emitting elements cooperate with each other to form a display image; wherein, the light-emitting element includes a plurality of red light-emitting elements, a plurality of green light-emitting elements, and one of the red light-emitting elements, one of the green light-emitting elements and one of the blue light-emitting elements constitute a pixel of the display image; wherein, the sensing elements are arranged in an array layout on the circuit substrate, and the sensing elements cooperate with each other to capture an image information.

3. The panel structure according to claim 1, wherein the light-emitting element is a micro LED without a substrate, which includes an n-type semiconductor, a light-emitting layer and a p-type semiconductor that are in a stacked arrangement.

4. The panel structure according to claim 1, wherein the light-emitting element is a mini LED, including a substrate, an n-type semiconductor, a light-emitting layer, and a p-type semiconductor that are in a stacked arrangement.

5. The panel structure according to claim 1, wherein at least one of the light-emitting elements and at least one of the sensing elements cooperatively form a surface sensor for an object; wherein at least one light source generated by the light-emitting element is projected onto an object, the projection light source forms a reflection light source by reflection of the object, and the reflection light source is projected on at least one of the sensing elements to capture an image information of the object.

6. A panel structure, comprising:
a circuit substrate;
a light-emitting component including a plurality of light-emitting elements electrically connected to the circuit substrate as an image display; and
a sensing component including one or more sensing elements electrically connected to the circuit substrate as an image sensor;
wherein some or all of the light-emitting elements are staggeringly disposed with the sensing elements on the circuit substrate.

7. The panel structure according to claim 6, wherein the light-emitting elements are arranged on the circuit substrate in an array layout, and the light sources generated by the light-emitting elements cooperatively form a display image; wherein the light-emitting element includes a plurality of red light-emitting elements, a plurality of green light-emitting elements, and a plurality of blue light-emitting elements, and one of the red light-emitting elements, one of the green light-emitting elements and one of the blue light-emitting elements constitute a pixel of the display image; wherein the sensing elements are arranged on the circuit substrate in an array layout, and the sensing elements cooperate with each other to capture an image information.

8. The panel structure according to claim 6, wherein the light-emitting element is a micro LED without a substrate, which includes an n-type semiconductor, a light-emitting layer and a p-type semiconductor that are in a stacked arrangement.

9. The panel structure according to claim 6, wherein the light-emitting element is a mini LED, including a substrate, an n-type semiconductor, a light-emitting layer, and a p-type semiconductor that are in a stacked arrangement.

10. The panel structure according to claim 6, wherein at least one of the light-emitting elements and at least one of the sensing elements cooperatively form a surface sensor for an object; wherein at least one light source generated by the light-emitting element is projected onto an object, the projection light source forms a reflection light source by reflection of the object, and the reflection light source is projected on at least one of the sensing elements to capture an image information of the object.
